(19) United States
(12) Patent Application Publication
(10) Pub. No.: US 2010/0003492 A1
(43) Pub. Date: Jan. 7, 2010

(54) HIGH QUALITY LARGE AREA BULK NON-POLAR OR SEMIPOLAR GALLIUM BASED SUBSTRATES AND METHODS

(75) Inventor: MARK P. D'EVELYN, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SORAA, INC., Goleta, CA (US)

(21) Appl. No.: 12/497,969

(22) Filed: Jul. 6, 2009

Related U.S. Application Data
(60) Provisional application No. 61/078,704, filed on Jul. 7, 2008.

(51) Int. Cl. B32B 9/00; C30B 23/02; H01B 1/02; B28D 1/02

(52) U.S. Cl. 428/220; 117/84; 252/518.1; 125/12

(57) ABSTRACT

A large area nitride crystal, comprising gallium and nitrogen, with a non-polar or semi-polar large-area face, is disclosed, along with a method for making. The crystal is useful as a substrate for a light emitting diode, a laser diode, a transistor, a photodetector, a solar cell, or for photoelectrochemical water splitting for hydrogen generation.

### CROSS-REFERENCES TO RELATED APPLICATIONS

This application claims priority to U.S. Provisional Patent Application No. 61/078,704, filed Jul. 7, 2008, commonly owned and incorporated herein by reference for all purposes.

### STATEMENT AS TO RIGHTS TO INVENTIONS MADE UNDER FEDERALLY SPONSORED RESEARCH AND DEVELOPMENT

Not applicable

### REFERENCE TO A “SEQUENCE LISTING,” A TABLE, OR A COMPUTER PROGRAM LISTING APPENDIX SUBMITTED ON A COMPACT DISK

Not applicable

### BACKGROUND OF THE INVENTION

The present invention relates generally to techniques for processing materials for manufacture of gallium based substrates. More specifically, embodiments of the invention include techniques for growing large area substrates using a combination of processing techniques. Merely by way of example, the invention can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photo electrochemical water splitting and hydrogen generation, photo detectors, integrated circuits, and transistors, and others.

Gallium nitride (GaN) based optoelectronic and electronic devices are of tremendous commercial importance. The quality and reliability of these devices, however, is compromised by high defect levels, particularly threading dislocations, grain boundaries, and strain in semiconductor layers of the devices. Dislocations can arise from lattice mismatch of GaN based semiconductor layers to a non-GaN substrate such as sapphire or silicon carbide. Grain boundaries can arise from the coalescence fronts of epitaxially-overgrown layers. Additional defects can arise from thermal expansion mismatch, impurities, and tilt boundaries, depending on the details of the growth method of the layers.

The presence of defects has a deleterious effect on epitaxially-grown layers. Such effect includes compromising electronic device performance. To overcome these defects, techniques have been proposed that require complex, tedious fabrication processes to reduce the concentration and/or impact of the defects. While a substantial number of conventional growth methods for gallium nitride crystals have been proposed, limitations still exist. That is, conventional methods still merit improvement to be cost effective and efficient.

Progress has been made in the growth of large-area c-plane gallium nitride crystals, typically with a (0001) orientation. The large-area c-plane gallium nitride crystals generally come in 2 inch diameter, free-standing (0001) GaN substrates and are generally available commercially. The non-polar planes of gallium nitride, such as (10-10) and (11-20), and the semi-polar planes of gallium nitride, such as (10-11), (10-12), (1-013), and (11-22), are attractive for a number of applications. Unfortunately, no large area, high quality non-polar or semi-polar GaN wafers are generally available for large scale commercial applications.

Several conventional techniques indicate growth of thick layers of c-plane gallium nitride by HVPE, from which transverse slices may be cut to prepare non-polar or semi-polar wafers. For example, Motoki [U.S. Pat. No. 6,468,347] discloses HVPE growth of a c-plane-oriented GaN single crystal ingot that is 2″ in diameter and 25 mm thick. Motoki deliberately grows a facet structure on the c-plane surface so as to attract dislocations. This method produces c-plane wafers with regions of high dislocation density, quantified as the etch pit density, separated by regions of dislocation density as low as 10⁴ cm⁻². Melnik [US 2005/0164044A1] also discloses the HVPE growth of c-plane GaN crystals up to 12 mm thick, with a c-plane dislocation density below 10⁵ cm⁻² and an x-ray diffraction rocking curve full-width-at-half-maximum (FWHM) of 60-360 arc seconds. Oshima [US 2006/0228870A1] discloses a multi-step HVPE method for growing a thick c-plane-oriented GaN crystal, cutting the crystal in a direction parallel to the propagation direction of threading dislocations, and then growing on the cut surface. Other techniques may also exist.

The aforementioned methods, however, suffer from some limitations. In order to achieve large area, the methods generally use a non-gallium-nitride crystal as the starting substrate, for example, sapphire or gallium arsenide. Strain and other factors resulting from the mismatch in lattice constants typically causes the growth surface to roughen and facet after growing a thick layer. This phenomenon, and an associated decrease in crystalline quality, has the effect of limiting the practical thickness of the HVPE-grown initial layer to about 8-15 mm. In addition, the strain together with a mismatch in the coefficients of thermal expansion typically produces a significant bow in the GaN-on-substrate composite, which remains even after removal of the original substrate. As a consequence, it is difficult to prepare transverse slices of c-plane-HVPE-grown GaN that are longer than about 15-20 mm. Thus, it is difficult to prepare non-polar GaN substrates by transverse cutting of HVPE-grown c-plane GaN that are larger than about 8-15 mm in the c direction by about 15-20 mm in a transverse direction (e.g., a or m). For preparation of semi-polar GaN substrates the maximum dimensions are slightly larger but are still limited.

In another approach to preparation of large-area non-polar and semi-polar GaN substrates, Haskell, Baker, et al. [U.S. Pat. No. 7,208,393, U.S. Pat. No. 7,220,658, US 2007/0015345A1], disclose HVPE deposition of a non-polar GaN layer on a non-GaN substrate such as LiAlO₂, sapphire, or spinel, together with reduction in the dislocation density by an epitaxial lateral overgrowth. In the case of epitaxial lateral overgrowth of a-plane GaN on r-plane sapphire, the laterally-grown GaN wings above a SiO₂ mask layer had a threading dislocation density below 5'10⁶ cm⁻² and a stacking fault density below 3×10³ cm⁻¹. However, considerably higher dislocation densities and stacking-fault concentrations were present in the regions above windows in the mask. In addition, the N-face wings retained high concentrations of stacking faults and Shockley partial dislocations, and defective coalescence fronts were present where adjacent laterally-grown wings met. The x-ray rocking curve full-width-at-half-maximum (FWHM) values were 750 arc-sec and 1250 arc-sec for the 11-20 and 10-10 reflections, respectively. These methods therefore do not provide an efficient technique for achieving large-area non-polar or semi-polar substrates with low values of the threading dislocation density, stacking fault density, and x-ray rocking curve FWHM over the entire substrate surface. These defect structures, along with those associated with coalescence fronts, would persist even if the GaN layer was grown to a much greater thickness, for example, to form an ingot or boule. These and other limitations of conventional techniques may be described further throughout the present specification.

From the above, it is seen that techniques for improving crystal growth are highly desirable.

### BRIEF SUMMARY OF THE INVENTION

According to the present invention, techniques related to techniques for processing materials for manufacture of gallium based substrates are provided. More specifically, embodiments of the invention include techniques for growing large area substrates using a combination of processing techniques. Merely by way of example, the invention can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photo electrochemical water splitting and hydrogen generation, photodetectors, integrated circuits, and transistors, and others.

In a specific embodiment, the present method and resulting device combines several bulk growth methods to grow large area non-polar and semi-polar GaN substrates with high crystalline quality without the characteristic defects associated with epitaxial lateral overgrowth.

In an alternative specific embodiment, the present invention provides a gallium based crystal. The crystal device includes a first thickness of single crystalline material comprising gallium and nitrogen having a surface region with an m-plane orientation. In a specific embodiment the first thickness of single crystalline material has a c-direction length of greater than about 1 centimeter to about 30 centimeters and an a-direction length of greater than about 1 centimeter to about 30 centimeters. In a specific embodiment, the first thickness of crystalline material has an m-direction thickness of at least 0.1 millimeter to about 10 millimeters. The crystal device also has a second thickness of single crystalline material deposited overlying the surface region in the m-plane. The second thickness of single crystal material comprises gallium and nitrogen. In a specific embodiment, the second thickness of single crystalline material has an m-direction thickness of at least 25 microns up to 50 millimeters. In a preferred embodiment, the first thickness and the second thickness are substantially free of stacking faults and coalescence fronts and the total impurity concentration in the second thickness is greater than the total impurity concentration in the first thickness.

In a specific embodiment, the second thickness of crystalline material is deposited ammonothermally and the second thickness of crystalline material has an m-plane dislocation density of 10⁶ cm⁻² and less and an unintentional impurity content of 10¹⁹ cm⁻³ and less. Still optionally, the first thickness of single crystal material comprises an m-oriented seed crystal whose central region is characterized by a c-plane dislocation density of between about 10⁴ cm⁻² to 10⁸ cm⁻² and having a 1-100 x-ray rocking curve full-width-at-half-maximum FWHM less than 300 arc seconds and a first total impurity concentration below about 10¹⁸ cm⁻³ and an oxygen concentration below about 10¹⁷ cm⁻³, a hydrogen concentration below about 2×10¹⁷ cm⁻³, and a sodium concentration below about 10¹⁶ cm⁻³ and a laterally grown single crystalline region in the c-direction by a c-plane dislocation density of between about 10⁴ cm2 to 10⁸ cm⁻² and having a 1-100 x-ray rocking curve full-width-at-half-maximum FWHM less than 300 arc seconds and a second total impurity concentration. In a specific embodiment, the second total impurity concentration is higher than the first total impurity concentration. Of course, there can be other variations, modifications, and alternatives.

In yet an alternative specific embodiment, the invention provides a gallium based crystal device. The device has a first thickness of single crystalline material comprising gallium and nitrogen having a surface region with an a-plane orientation. In a specific embodiment, the first thickness of single crystalline material has a c-direction length of greater than about 1 centimeter to about 30 centimeters and an m-direction length of greater than about 1 centimeter to about 30 centimeters. The first thickness of crystalline material has an m-direction thickness of at least 0.1 millimeter to about 10 millimeters according to a specific embodiment. The device has a second thickness of single crystalline material deposited overlying the surface region in the a-plane. The second thickness of single crystal material comprises gallium and nitrogen and has an a-direction thickness of at least 25 microns up to 50 millimeters. In a specific embodiment, the first thickness and the second thickness are substantially free of stacking faults and coalescence fronts and the total impurity concentration in the second thickness is greater than the total impurity concentration in the first thickness.

Still further, the present invention provides a gallium nitride thickness of material. The material has a first thickness of single crystal material comprising an m-plane oriented crystal characterized by a c-plane dislocation density of between about 10⁴ cm⁻² to 10⁸ cm⁻² and has a 1-100 x-ray rocking curve full-width-at-half-maximum FWHM less than about 150 arc seconds and a first total impurity concentration below about 10¹⁸ cm⁻³ and an oxygen concentration below about 10¹⁷ cm⁻³ and a hydrogen concentration below about 2×10¹⁷ cm⁻³, and a sodium concentration below about 10¹⁶ cm⁻³ and a laterally grown single crystalline region in the c-direction by a c-plane dislocation density of between about 10⁴ cm⁻² to 10⁸ cm⁻² and has a 1-100 x-ray rocking curve full-width-at-half-maximum FWHM less than about 150 arc seconds and a second total impurity concentration. In a specific embodiment, the second total impurity concentration is higher than the first total impurity concentration.

In yet an alternative specific embodiment, the present invention provides a method for slicing one or more substrates. The method includes providing a gallium based substrate comprising a first thickness of single crystalline material comprising gallium and nitrogen having a surface region in an m-plane. In a specific embodiment, the first thickness of single crystalline material has a c-direction length of greater than about 1 centimeter to about 30 centimeters and an a-direction length of greater than about 1 centimeter to about 30 centimeters. In a specific embodiment, the first thickness of crystalline material has an m-direction thickness of at least 0.1 millimeter to about 10 millimeters. The material also has a second thickness of single crystalline material deposited overlying the surface region in the m-plane. The second thickness of single crystal material comprises gallium and nitrogen. The second thickness of single crystalline material has an m-direction thickness of at least 25 microns up to 50 millimeters. The method also includes orienting the gallium based substrate. The method includes slicing a thickness of substrate material from the gallium based substrate to remove the thickness of substrate material from a remaining portion of the gallium based substrate. In a specific embodiment, the thickness of substrate material is about 0.1 millimeter and greater.

Moreover, the present invention provides a method for fabricating a seed crystal. The method includes providing an m-plane oriented seed crystal characterized by a c-plane dislocation density of between about 10⁴ cm⁻² to 10⁸ cm⁻² and having a 1-100 x-ray rocking curve full-width-at-half-maximum FWHM less than about 300 arc seconds and a first total impurity concentration below about 10¹⁸ cm⁻³ and an oxygen concentration below about 10¹⁷ cm⁻³ and a hydrogen concentration below about 2×10¹⁷ cm⁻³, and a sodium concentration below about 10¹⁶ cm⁻³. The method also includes growing in a lateral direction a single crystalline thickness of material in either or both a +c-direction and −c direction using first ammonothermal process. In a specific embodiment, the single crystalline thickness of material has a c-plane dislocation density of between about 10⁴ cm⁻² to 10⁸ cm⁻² and having a 1-100 x-ray rocking curve full-width-at-half-maximum FWHM less than about 300 arc seconds and a second total impurity concentration, which is higher than the first total impurity concentration.

Still further, the present invention provides an alternative method of fabricating a gallium based substrate. The method includes providing a first thickness of single crystalline material comprising gallium and nitrogen having a surface region in an m-plane orientation. In a specific embodiment, the first thickness of single crystalline material has a c-direction length of greater than about 1 centimeter to about 30 centimeters and an a-direction length of greater than about 1 centimeter to about 30 centimeters. The first thickness of crystalline material has an m-direction thickness of at least 0.1 millimeter to about 10 millimeters. In a specific embodiment, the present method includes growing a second thickness of single crystalline material using a deposition process overlying the surface region in the m-plane. In a specific embodiment, the second thickness of single crystal material comprises gallium and nitrogen. The second thickness of single crystalline material has an m-direction thickness of at least 25 microns up to 50 millimeters.

Moreover, the present invention provides a method of fabricating devices, e.g., electrical, optical. The method includes providing a composite seed crystal comprising a first region of first gallium and nitrogen containing material and a second region of second gallium and nitrogen containing material. Depending upon the embodiment, the impurity or impurity concentration may be different between the first and second regions. In a specific embodiment, the method includes forming one or more thicknesses of gallium and nitrogen containing material overlying one or more portions of the composite seed crystal. The method also includes using one or more regions of the one or more thicknesses of the gallium and nitrogen containing material for fabricating of at least an optical and/or an electrical device.

Still further, the present invention provides a composite seed crystal comprising a first region of first gallium and nitrogen containing material and a second region of second gallium and nitrogen containing material. In a specific embodiment, the present invention provides an alternative a composite seed crystal comprising two or more regions, the two or more regions being made of a gallium and a nitrogen containing material, e.g., GaN.

Still further, the present invention provides a method for fabricating a gallium containing substrate material. The method includes providing a composite seed crystal comprising a first region and a second region in a specific embodiment. Preferably, the composite seed crystal is composed of a gallium containing material. In a specific embodiment, the first region is characterized by a first set of impurity concentrations and the second region is characterized by a second set of impurity concentrations. In one or more embodiments, a concentration of at least one of hydrogen, oxygen, sodium, potassium, fluorine, or chlorine differs by at least a factor of three between the first region and the second region. The method also includes growing a thickness of material overlying the composite seed material to cause formation of a gallium containing boule having a diameter of 1 centimeter and greater and a thickness of 1 millimeter and greater. The method also slices the gallium containing boule to form one or more gallium containing substrates. Electrical and/or optical devices may be formed on one or more portions of the gallium containing substrates according to a specific embodiment.

Benefits are achieved over pre-existing techniques using the present invention. In particular, the present invention enables a cost-effective technique for growth of large area crystals of non-polar or semipolar materials, including GaN, AlN, InN, InGaN, and AlInGaN and others. In a specific embodiment, the present method and resulting structure are relatively simple and cost effective to manufacture for commercial applications. In one or more embodiments, the invention provides one or more method using a combination of HVPE and ammonothermal processes or HVPE formed structures and ammono thermal processes, using more than one or two or other steps, to form large area substrates from gallium and nitrogen containing seed substrates, which may be composite. A specific embodiment also takes advantage of a combination of techniques, which solve a long standing need. In a preferred embodiment, the present non-polar or semi-polar substrate can have greater substrate area.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 is a simplified diagram illustrating a method of forming an m-plane seed crystal according to an embodiment of the present invention;

FIG. 2 is a simplified diagram illustrating optional steps of forming a large area GaN substrate according to an alternative embodiment of the present invention;

FIG. 3 is a simplified diagram illustrating a lateral growth process in the c-direction for a large area GaN substrate according to an alternative embodiment of the present invention;

FIG. 4 is a simplified diagram illustrating a vertical growth process in the m-direction for a large area GaN substrate according to an alternative embodiment of the present invention;

FIG. 5 is a simplified flow diagram illustrating an HVPE process according to an embodiment of the present invention; and

FIG. 6 is a simplified diagram illustrating a process for slicing substrates of different planes according to an embodiment of the present invention.

### DETAILED DESCRIPTION OF THE INVENTION

According to the present invention, techniques related to techniques for processing materials for manufacture of gallium based substrates are provided. More specifically, embodiments of the invention include techniques for growing large area substrates using a combination of processing techniques. Merely by way of example, the invention can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photo electrochemical water splitting and hydrogen generation, photodetectors, integrated circuits, and transistors, and others.

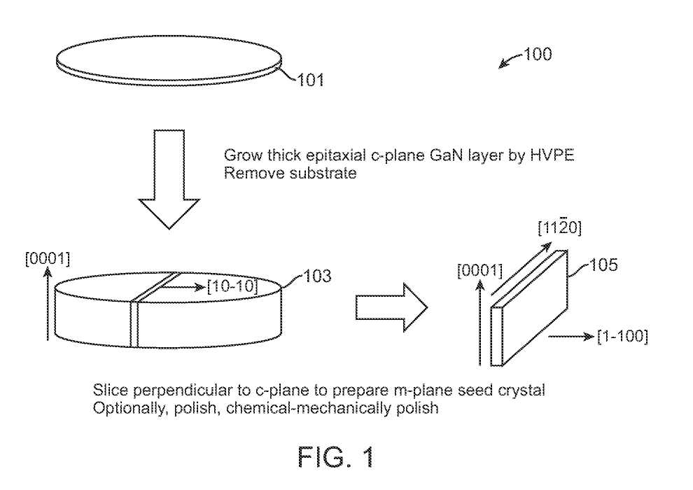

FIG. 1 is a simplified diagram 100 illustrating a method for forming a GaN substrate using HVPE according to a specific embodiment of the present invention. This diagram is merely an illustration and should not unduly limit the scope of the claims herein. One of ordinary skill in the art would recognize other variations, modifications, and alternatives. As shown, in one or more embodiments, the starting point for the present invention is a non-polar slice or wafer, with an m-plane (1-100) orientation, an a-plane orientation (11-20), or an intermediate non-polar orientation (h,k,−(h+k),0) where h and k are integers. In another set of embodiments, the starting point for the present invention is a semi-polar slice or wafer, with an orientation (h,k,−(h+k),1) where h, k, and 1 are integers and 1 is non-zero. A method for forming the non-polar slice 101 or wafer is shown in FIG. 1. A thick c-plane GaN layer 103 may be grown on a substrate by HVPE, according to methods that are known in the art according to a specific embodiment. An example of such method is shown in US patent application 2006/0228870, which is incorporated by reference herein. In a specific embodiment, the substrate may be selected from c-plane GaN, c-plane sapphire, spinel MgAl₂O₄(111), GaAs(111), Si(111), any combination of these, or the like. The c-plane GaN layer may have a thickness between 8 mm and 25 mm according to a specific embodiment. After growth, the substrate may be removed from the thick GaN layer by methods that are known in the art. In the case of a GaAs(111) or Si(111) substrate, the substrate may simply be dissolved in a suitable acid according to a specific embodiment. In the case of sapphire, the substrate may be removed by laser liftoff or by selective dissolution in molten KBF₄ or other suitable techniques. Of course, there can be other variations, modifications, and alternatives.

In a specific embodiment, the present method slices substrates in a non-polar configuration. One 105 or more non-polar slices may be prepared by making two or more saw cuts perpendicular to the (0001) c plane, for example, parallel to the (11-20) plane or parallel to the (1-100) plane. The slice may have a thickness between about 0.1 mm and 10 mm, but there can be others according to a specific embodiment. After sawing, the wafers may be lapped, polished, electrochemically polished, photoelectrochemically polished, reactive-ion-etched, and/or chemical-mechanically polished according to methods that are known in the art. The non-polar slice wafer or crystal may contain several crystallites separated by low-angle grain boundaries but is free from coalescence fronts of the type observed in epitaxial lateral overgrowth. Of course, there can be other variations, modifications, and alternatives. In one specific embodiment, the slice has large-area faces with an m-plane orientation, that is, within ±5 degrees of [1-100], within ±2 degrees of [1-100], within ±1 degrees of [1-100], within ±0.5 degrees of [1-100], or within ±0.2 degrees of [1-100]. In another embodiment, the slice has large-area faces with an a-plane orientation, that is, within ±5 degrees of [11-20], within ±2 degrees of [11-20], within ±1 degrees of [11-20], within ±0.5 degrees of [11-20], or within ±0.2 degrees of [11-20].

In another specific embodiment, the present method slices substrates in a semi-polar configuration. One or more semi-polar slices may be prepared by making two or more saw cuts at an oblique angle to the (0001) c plane, for example, parallel to the (11-22) plane or parallel to the (1-101) plane. The slice may have a thickness between about 0.1 mm and 10 mm, but there can be others according to a specific embodiment. After sawing, the wafers may be lapped, polished, electrochemically polished, photoelectrochemically polished, reactive-ion-etched, and/or chemical-mechanically polished (or any of combinations) according to methods that are known in the art. The semi-polar slice wafer or crystal may contain several crystallites separated by low-angle grain boundaries but is free from coalescence fronts of the type observed in epitaxial lateral overgrowth. Of course, there can be other variations, modifications, and alternatives. In one specific embodiment, the slice has large-area faces with a [11-22] orientation, that is, within ±5 degrees of [11-22], within ±2 degrees of [11-22], within ±1 degrees of [11-22], within ±0.5 degrees of [11-22], or within ±0.2 degrees of [11-22]. In another embodiment, the slice has large-area faces with a (1-101) orientation, that is, within ±5 degrees of [1-101], within ±2 degrees of [1-101], within ±1 degrees of [1-101], within ±0.5 degrees of [1-101], or within ±0.2 degrees of [1-101].

Depending upon the embodiment, the c face includes one or more characteristics. In a specific embodiment, the (0001) c face of the slices may be rough, due to faceting that occurred during the original growth step. In a specific embodiment, the root-mean-square (rms) surface roughness can be about 10 microns to about 1 mm, measured over a lateral area of about 1 cm². The slices may have a c-plane dislocation density of about 10⁶-10⁹ cm⁻², depending on location, with the lower values occurring near the (0001) face and the higher values occurring near the (000-1) face. The dislocations may run approximately in the c direction, so that the dislocation density on the newly prepared non-polar surfaces is significantly less than 10⁶ cm⁻², and is typically below 10⁵ cm⁻² or below 10⁴ cm⁻².

The slice may have a total impurity concentration below 1×10¹⁸ cm⁻³. The slice may have impurity concentrations of oxygen (O), hydrogen (H), carbon (C), sodium (Na), and potassium (K) below 1×10¹⁷ cm⁻³, 2×10¹⁷ cm⁻³, 1×10¹⁷ cm⁻³, 1×10¹⁶ cm⁻³, and 1×10¹⁶ cm⁻³, respectively, as quantified by calibrated secondary ion mass spectrometry (SIMS), glow discharge mass spectrometry (GDMS), interstitial gas analysis (IGA), or the like. In some embodiments the impurity concentration of oxygen is less than 3×10¹⁶ cm⁻³ or less than 1×10¹⁶ cm⁻³. In some embodiments the impurity concentration of hydrogen is less than 1×10¹⁷ cm⁻³ or less than 3×10¹⁶ cm⁻³. In some embodiments the impurity concentration of carbon is less than 3×10¹⁶ cm⁻³ , less than 1×10¹⁶ cm⁻³, or less than 3×10¹⁵ cm⁻³. In some embodiments the impurity concentrations of sodium and of potassium are less than 3×10¹⁵ cm⁻³ or less than 1×10¹⁵ cm⁻³. The slice may have impurity concentrations of fluorine (F) and chlorine (Cl) below 1×10¹⁵ cm⁻³ and 1×10¹⁵ cm⁻³, respectively. Of course, there can be other variations, modifications, and alternatives. The slice is substantially free of stacking faults, with a concentration below 100 cm⁻¹. In one specific embodiment the slice has an m-plane orientation and the full-width-at-half-maximum (FWHM) of the 1-100 x-ray rocking curve is below 300 arc sec. In another, the FWHM is below 150 arc sec. In a different specific embodiment, the slice has an a-plane orientation and the full-width-at-half-maximum (FWHM) of the 11-20 x-ray rocking curve is below 300 arc sec. In another, the FWHM is below 150 arc sec. Other characteristics may also exist depending upon the specific embodiment.

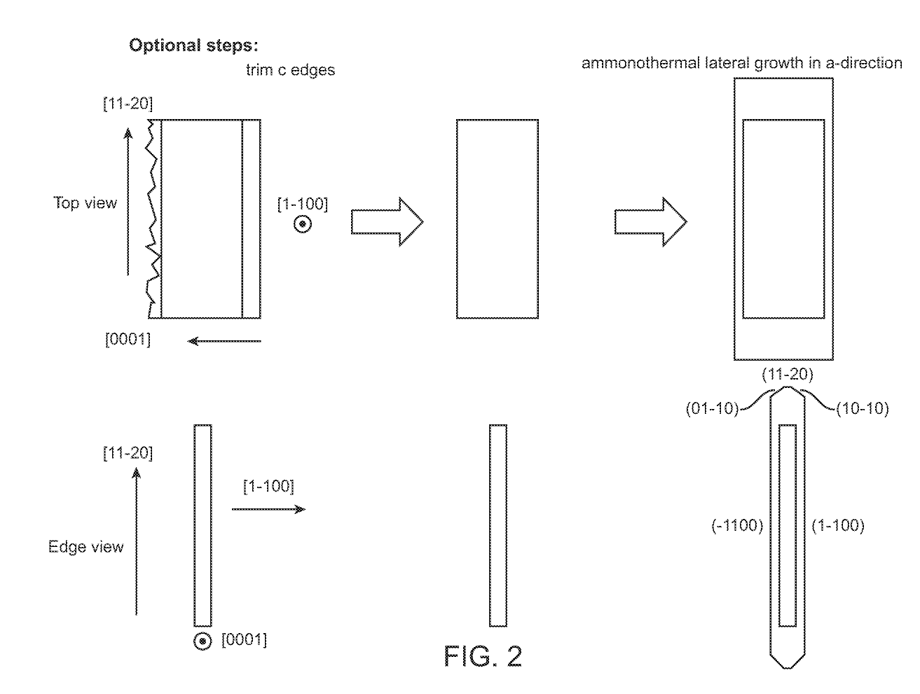

In a specific embodiment, the present method includes one or more processes to treat the starting seed crystal. FIG. 2 is a simplified diagram illustrating optional steps of forming a large area GaN substrate according to an alternative embodiment of the present invention according to a specific embodiment of the present invention. This diagram is merely an illustration and should not unduly limit the scope of the claims herein. One of ordinary skill in the art would recognize other variations, modifications, and alternatives. As shown, the quality of the non-polar slice may be improved by removing the (0001) and/or (000-1) c-plane edges, as shown in FIG. 2. Removal of the (0001) edge may allow for elimination of facets on the edge of the crystal and provide a better starting point for subsequent crystal growth or other process. Removal of 0.5-2 mm of the (000-1) edge allows for removal of the region with the highest dislocation density, so that subsequent crystal growth in the (000-1) −c direction may start with a dislocation density in the 10⁷ cm⁻² range or below, rather than in the 10⁸ cm⁻² to 10⁹ cm⁻² range. The edges may be removed by sawcutting, laser cutting, cleavage, lapping, or the like, among other techniques. After removal of the edges, the newly formed edges may be lapped, polished, electrochemically polished, photoelectrochemically polished, reactive-ion-etched, and/or chemical-mechanically polished. Of course, there can be other variations, modifications, and alternatives.

In crystal growth processes, the impurity levels in seed crystals are similar to those in the crystal that is grown upon the seed. Such a process minimizes strains and possible deleterious effects such as misfit dislocation generation, unstable surface morphologies, and crack formation. Surprisingly, growth of bulk gallium nitride layers with a significant variation in impurity levels does not lead to severe consequences, as long as the variations are not too large, and offers significant benefits. In particular, this relative insensitivity to impurity gradients within a grown, composite gallium nitride crystal enables the crystal grower to take advantage of the different crystallographic growth-rate ratios achievable with different growth techniques and chemistries in order to grow large, high quality gallium nitride crystals. The composite gallium containing crystal comprises a first region and a second region, the composite seed crystal being composed of a gallium containing material, the first region being characterized by a first set of impurity levels or concentrations and the second region being characterized by a second set of impurity levels or concentrations. The transition between the first set of impurity levels and the second set of impurity levels may occur within a transition thickness of less than about 100 microns, less than about 10 microns, or less than about 1 micron. In some embodiments, the composite crystal further comprises a third region, with a third set of impurity levels or concentrations. In still other embodiments, the composite crystal further comprises a fourth region, with a fourth set of impurity levels or concentrations. The transition between the second region and the third region, and/or between the third region and the fourth region, may occur within a transition thickness of less than about 100 microns, less than about 10 microns, or less than about 1 micron. In one or more embodiments, a concentration of at least one of hydrogen, oxygen, sodium, potassium, fluorine, or chlorine differs by at least a factor of three between the first region and the second region, between the second region and the third region, and/or between the third region and the fourth region. In one or more embodiments, a concentration of at least one of hydrogen, oxygen, sodium, potassium, fluorine, or chlorine differs by at least a factor of ten between the first region and the second region, between the second region and the third region, and/or between the third region and the fourth region. The composite gallium containing crystal may be formed using at least two, at least three, or at least four different growth chemistries and/or growth conditions. Again, there can be other variations, modifications, and alternatives.

In a specific embodiment, the non-polar slice has an m-plane orientation and is used as a seed crystal for ammonothermal growth, under conditions favoring growth in the a direction, as shown in FIG. 2. For example, an opening or hole is laser-cut near one end of the non-polar slice seed crystal. The crystal is hung from a silver wire or other suitable technique inside a silver capsule below a baffle. Polycrystalline GaN raw material, NH₄F mineralizer, and ammonia are added to the capsule with a ratio of approximately 15:1:8.5, but there can be other ratios according to a specific embodiment. The sealed capsule is placed in a cell in a zero-stroke high pressure apparatus or other suitable apparatus. The cell is heated at about 11 degrees Celsius per minute until the temperature of the bottom of the capsule is approximately 700 degrees Celsius and the temperature of the top half of the capsule is approximately 650 degrees Celsius, as measured by type K thermocouples according to a specific embodiment. The temperature of the top half of the heater is then increased until the temperature gradient ΔT decreases to zero. After holding at ΔT=0 for 1 hour, the temperature of the top half of the capsule is decreased at 5 degrees Celsius per hour until ΔT increases to approximately 30 degrees Celsius, and the temperatures are held at these values for a predetermined time. In another specific embodiment, the semi-polar slice is used as a seed crystal for ammonothermal growth, under conditions favoring growth in the a direction.

In a specific embodiment, the cell is then cooled and removed from the zero-stroke high pressure apparatus. Cooling occurs by thermal conduction to a water-cooled element within the high pressure apparatus, according to a specific embodiment. The seed crystal grows in the a direction at a rate as high as about 60 micron per hour until the edges of the crystal become terminated by m planes, but can be higher or slightly lower in other applications. The m plane edges and the m-plane thickness of the crystal grow at a rate as high as about 17 microns per hour or greater, or slightly less according to a specific embodiment. In the example shown in FIG. 2, growth takes place principally in the [11-20] and [−1-120] directions, with a lesser amount of growth in the [1-100] and [−1100] directions and in the [0001] and [000-1] directions (latter not shown). The edges of the short a planes begin to become terminated by m planes, e.g., (01-10) and (10-10) surrounding a (11-20) facet.

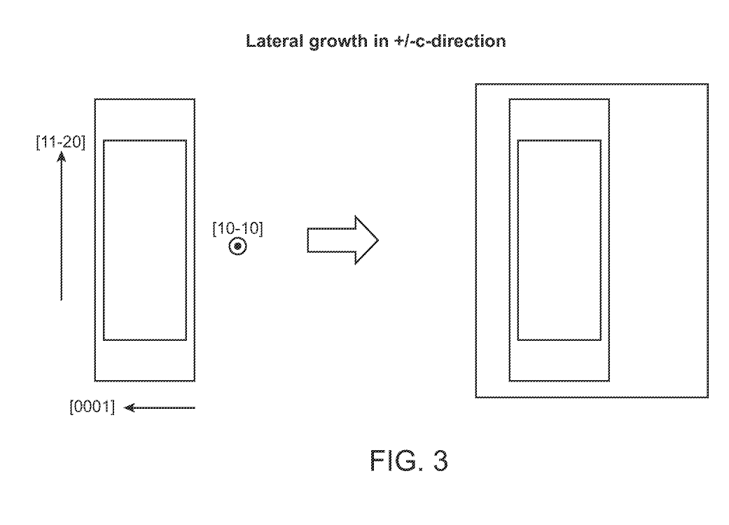

In a specific embodiment, the non-polar slice crystal is used as a seed crystal for ammonothermal growth, under conditions favoring growth in the +c and/or −c directions, as shown in FIG. 3. For example, if it is not already present, a hole is laser-cut near one end of the non-polar slice seed crystal. The crystal is hung from a silver wire or other suitable technique inside a silver capsule below a baffle. Polycrystalline GaN raw material, GaF₃ mineralizer, and ammonia are added to the capsule with a ratio of approximately 10:1.1:8.5, but there can be other ratios according to a specific embodiment. The sealed capsule is placed in a cell in a zero-stroke high pressure apparatus or other suitable techniques. The cell is heated until the temperature of the bottom of the capsule is approximately 750 degrees Celsius and the temperature of the top half of the capsule is approximately 705 degrees Celsius, as measured by type K thermocouples. The temperatures are held at these values for a predetermined period of time. The cell is then cooled and removed from the zero-stroke high pressure apparatus. The seed crystal grows in the +c and −c directions at a rate between about 10 microns per hour and 20 microns per hour. The two crystallographic directions are inequivalent in GaN, so the growth rates in the two directions may or may not be the same. The thickness of the non-polar slice crystal increases from its initial value by between 50 microns and 100 millimeters, implying that the thickness of ammonothermally-deposited material on each large area nonpolar face was between 25 microns and 50 millimeters.

In a specific embodiment, lateral growth in the a directions and in the ±c directions is conducted in a single crystal growth run. In an embodiment, crystal growth conditions are adjusted within a crystal growth run to promote a-direction growth versus ±c direction growth. In another embodiment, lateral growth in the ±c directions and in at least one non-polar direction occurs simultaneously.

The ammonothermally-laterally-grown non-polar slice crystal has lateral dimensions, that is, in the c-direction and in the direction perpendicular to c and to the large area surface, between about 1 centimeter and about 30 centimeters. The central width of the ammonothermally-laterally-grown non-polar slice crystal, that is, the region of the crystal lateral to the original non-polar seed crystal, may have a c-plane dislocation density of about 10⁴-10⁸ cm⁻². The dislocations may run approximately in the c direction. The top and bottom surface of the ammonothermally-laterally-grown non-polar slice crystal, that is, the region of the crystal that has grown perpendicular to the large area faces of the original non-polar seed crystal, both above and below the original seed crystal and lateral to it, may have a c-plane dislocation density of about 10⁰-10⁵ cm⁻², as this growth took place in a lateral direction with respect to the original dislocations in the non-polar seed crystal. In a specific embodiment, the top and bottom surfaces of the ammonothermally-laterally-grown non-polar slice crystal may have impurity concentrations of O, H, C, Na, and K between about 1×10¹⁷ cm⁻³ and 1×10¹⁹ cm⁻³, between about 1×10¹⁷ cm⁻³ and 2×10¹⁹ cm⁻³, below 1×10¹⁷ cm⁻³, below 1×10¹⁶ cm⁻³, and below 1×10¹⁶ cm⁻³, respectively, as quantified by calibrated secondary ion mass spectrometry (SIMS). In another embodiment, the top and bottom surfaces of the ammonothermally-laterally-grown non-polar slice crystal may have impurity concentrations of O, H, C, and at least one of Na and K between about 1×10¹⁷ cm⁻³ and 1×10¹⁹ cm⁻³, between about 1×10¹⁷ cm⁻³ and 2×10¹⁹ cm⁻³, below 1×10¹⁷ cm⁻³, and between about 3×10¹⁵ cm⁻³ and 1×10¹⁸ cm⁻³, respectively, as quantified by calibrated secondary ion mass spectrometry (SIMS). In still another embodiment, the top and bottom surfaces of the ammonothermally-laterally-grown non-polar slice crystal may have impurity concentrations of O, H, C, and at least one of F and Cl between about 1×10¹⁷ cm⁻³ and 1×10¹⁹ cm⁻³, between about 1×10¹⁷ cm⁻³ and 2×10¹⁹ cm⁻³, below 1×10¹⁷ cm⁻³, and between about 1×10¹⁵ cm⁻³ and 1×10¹⁷ cm⁻³, respectively, as quantified by calibrated secondary ion mass spectrometry (SIMS). In some embodiments, the top and bottom surfaces of the ammonothermally-laterally-grown non-polar slice crystal may have impurity concentrations of H between about 5×10¹⁷ cm⁻³ and 1×10¹⁹ cm⁻³, as quantified by calibrated secondary ion mass spectrometry (SIMS). In a specific embodiment, at least one of the top and bottom surface of the ammonothermally-laterally-grown non-polar slice crystal and the laterally-grown portion of the ammonothermally-laterally-grown non-polar slice crystal has an infrared absorption peak at about 3175 cm⁻¹, with an absorbance per unit thickness of greater than about 0.01 cm⁻¹. The ammonothermally-laterally-grown non-polar slice crystal may contain several crystallites separated by low-angle grain boundaries but is free from coalescence fronts of the type observed in epitaxial lateral overgrowth.

In a specific embodiment, the ammonothermally-laterally-grown non-polar slice crystal has an m-plane orientation and the FWHM of the 1-100 x-ray rocking curve of at least one of the top surface and the bottom surface is below 1000 arc sec. In another embodiment, the FWHM of the 1-100 x-ray rocking curve of at least one of the top surface and the bottom surface is below 300 arc sec. In another embodiment, the FWHM of the 1-100 x-ray rocking curve of at least one of the top surface and the bottom surface is below 100 arc sec. The dislocation density on at least one large-area m-plane surface may be below 10⁶ cm⁻², below 10⁵ cm⁻², below 10⁴ cm⁻², below 10³ cm⁻², or below 10² cm⁻².

In a specific embodiment, the ammonothermally-laterally-grown non-polar slice crystal has an a-plane orientation and the FWHM of the 11-20 x-ray rocking curve of at least one of the top surface and the bottom surface is below 700 arc sec. In another embodiment, the FWHM of the 11-20 x-ray rocking curve of at least one of the top surface and the bottom surface is below 250 arc sec. In another embodiment, the FWHM of the 11-20 x-ray rocking curve of at least one of the top surface and the bottom surface is below 100 arc sec. The dislocation density on at least one large-area a-plane surface may be below 10⁶ cm⁻², below 10⁵ cm⁻², below 10⁴ cm⁻², below 10³ cm⁻², or below 10² cm⁻².

In another specific embodiment, the ammonothermally-laterally-grown semi-polar slice crystal has a {1-101} orientation and the FWHM of the 1-101 x-ray rocking curve of at least one of the top surface and the bottom surface is below 700 arc sec. In another embodiment, the FWHM of the 1-101 x-ray rocking curve of at least one of the top surface and the bottom surface is below 250 arc sec. In another embodiment, the FWHM of the 1-101 x-ray rocking curve of at least one of the top surface and the bottom surface is below 100 arc sec. The dislocation density on at least one large-area a-plane surface may be below 10⁶ cm⁻², below 10⁵ cm⁻², below 10⁴ cm⁻², below 10³ cm⁻², or below 10² cm⁻².

In a specific embodiment, the ammonothermally-laterally-grown non-polar or semi-polar slice crystal is lapped, polished, electrochemically polished, photoelectrochemically polished, reactive-ion-etched, and/or chemical-mechanically polished according to methods that are known in the art.

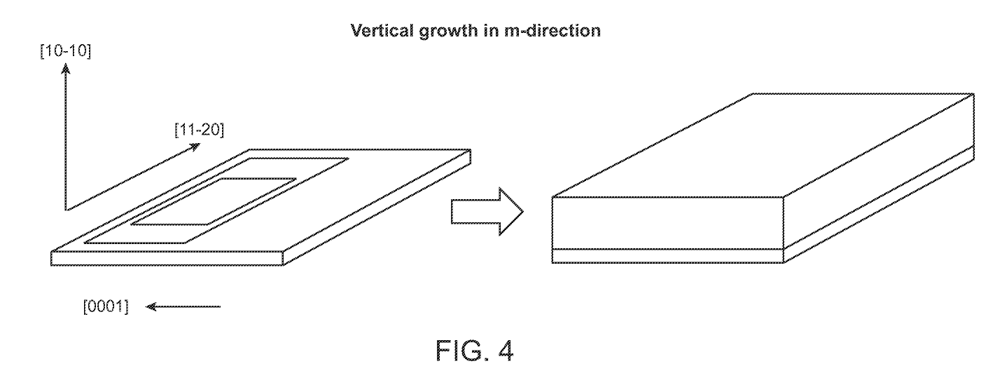

In one specific embodiment, the ammonothermally-laterally-grown non-polar or semi-polar slice crystal is then used as a substrate for HVPE growth, as shown in FIG. 4. Some dislocations may form at or near the interface between the ammonothermally-laterally-grown non-polar or semi-polar slice crystal and the newly HVPE-grown GaN material and propagate in the growth direction. However, their concentration is relatively low, for example, below 10⁶ cm⁻², below 10⁵ cm⁻², below 10⁴ cm⁻², below 10³ cm⁻², or below 10² cm⁻².

At least one ammonothermally-laterally-grown non-polar or semi-polar slice crystal is placed on or fixed against a substrate holder in an HVPE reactor. The reactor is capable of generating a gallium-containing halide compound, such as (but not limited to), a gallium monochloride (GaCl), by flowing gaseous hydrogen chloride (HCl) over or past molten metallic gallium at a temperature in excess of 700 degrees Celsius. The gallium-containing halide compound is transported to the substrate by a carrier gas. The carrier gas may comprise at least one of nitrogen, hydrogen, helium, or argon. In a specific embodiment, the carrier gas comprises hydrogen for the final growth stage in one or more of the gas streams in the reactor. Ammonia (NH₃) is also transported to the substrate, either in pure form or diluted with a carrier gas. In a specific embodiment, the reactor pressure is held below atmospheric pressure (760 Torr) for at least the final stage of GaN film growth. In an embodiment, the gas composition consists essentially of 32% N₂, 58% H₂, and the balance NH₃ and HCl, with a V:III ratio of 15:8, the growth pressure is 70 Torr, and the substrate temperature is 862 degrees Celsius. Growth is performed for a predetermined period of time, and occurs at rate between 1 and 400 microns per hour.

In another specific embodiment, the ammonothermally-laterally-grown non-polar or semi-polar slice crystal is then used as a substrate for ammonothermal growth, as shown in FIG. 4, under conditions favoring growth perpendicular to the large-area faces, for example, m faces. For example, if it is not already present, a hole (or opening or recessed region) is laser-cut near one end of the non-polar slice seed crystal. The crystal is hung from a silver wire or other suitable technique inside a silver capsule below a baffle. Polycrystalline GaN raw material, GaF₃ mineralizer, NH₄F mineralizer, and ammonia are added to the capsule with a ratio of approximately 10:1:0.13:9, but there can be other ratios according to a specific embodiment. The sealed capsule is placed in a cell in a zero-stroke high pressure apparatus or other suitable techniques. The cell is heated until the temperature of the bottom of the capsule is approximately 750 degrees Celsius and the temperature of the top half of the capsule is approximately 700 degrees Celsius, as measured by type K thermocouples, but there can be other temperatures. The temperatures are held at these values for a predetermined period of time. The cell is then cooled and removed from the zero-stroke high pressure apparatus. The seed crystal grows in the m directions at a rate between about 1 micron per hour and about 40 microns per hour. The thickness of the non-polar slice crystal increases from its initial value by between 50 microns and 100 millimeters, implying that the thickness of ammonothermally-deposited material on each large area nonpolar face is between 25 microns and 50 millimeters. In one specific embodiment, the thickness of ammonothermally-deposited material on each large area nonpolar face is 1 millimeter and greater. Some dislocations may form at or near the interface between the ammonothermally-laterally-grown non-polar or semi-polar slice crystal and the newly ammonothermally-grown GaN material and propagate in the growth direction. However, their concentration is relatively low, for example, below 10⁶ cm⁻², below 10⁵ cm⁻², below 10⁴ cm⁻², below 10³ cm⁻², or below 10² cm⁻².

In some embodiments, the ammonothermally-laterally-grown non-polar or semi-polar slice crystal is used as a substrate for further ammonothermal growth by simply changing the process conditions rather than by terminating the first ammonothermal process, removing the ammonothermally-laterally-grown non-polar or semi-polar slice crystal from the growth chamber, re-inserting it as a seed crystal in a growth chamber, and beginning a new or different ammonothermal growth process. For example, the process conditions may be changed by adjusting the average temperature of the growth chamber and/or by changing the temperature difference between the source or nutrient region of the growth chamber and the growth region of the growth chamber.

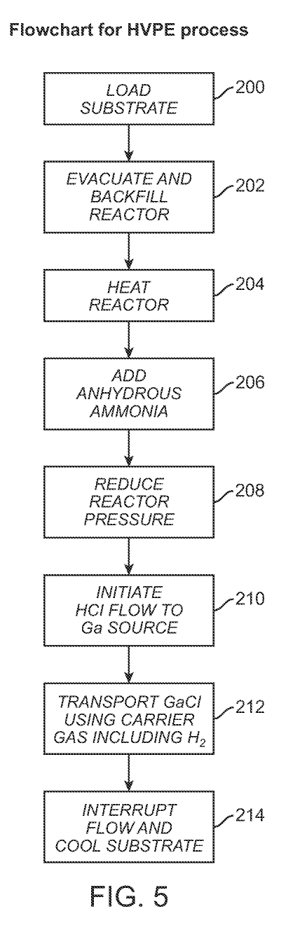

FIG. 5 is a flowchart that illustrates the steps of performing growth of planar m-plane GaN homoepitaxial films by hydride vapor phase epitaxy according to the preferred embodiment of the present invention. These steps comprise a typical growth sequence that yields high-quality, planar, m-plane GaN films using a conventional three-zone horizontal directed-flow HVPE system.

Block 200 represents the step of loading an ammonothermally-laterally-grown non-polar slice crystal into a reactor.

Block 202 represents the step of evacuating the reactor, preferably to a pressure below 0.09 Torr, and backfilling the reactor with purified nitrogen (N₂) gas to reduce oxygen and water vapor levels therein, before heating the reactor. This step is typically repeated to further reduce the oxygen and water vapor presence in the system.

Block 204 represents the step of in situ preparation of the substrate surface, comprising heating the substrate to a temperature between about 800 degrees Celsius and about 1040 degrees Celsius, with a gas composition comprising at least one of H₂, N₂, and NH₃ flowing through all channels in the system. The reactor pressure may be atmospheric (760 Torr), slightly above atmospheric pressure, or below atmospheric pressure. It is generally desirable to include a fraction of NH₃ in the gas stream during the reactor heating stage to prevent partial decomposition of the template.

Block 208 represents the step of reducing the reactor's pressure to a desired deposition pressure. In the preferred embodiment, the desired deposition pressure is below atmospheric pressure (760 Torr), and is generally less than 300 Torr. More specifically, the desired deposition pressure ranges from 5 to 100 Torr. In a preferred embodiment, the desired deposition pressure is approximately 76 Torr.

Block 210 represents the step of initiating a gaseous hydrogen chloride (HCl) flow to a gallium (Ga) source to begin growth of the m-plane GaN film directly on the substrate without the use of any low-temperature buffer or nucleation layers. Conventional metal source HVPE involves an in situ reaction of a halide compound, such as (but not limited) to, gaseous HCl with the metallic Ga at a temperature in excess of 700 degrees Celsius to form a metal halide species, such as gallium monochloride (GaCl).

Block 212 represents the step of transporting the GaCl to the substrate by a carrier gas that includes at least a fraction of hydrogen (H₂) in one or more of the gas streams in the reactor. The carrier gas may also include nitrogen, helium, or argon, or other non-reactive noble gases. Either in transport to the substrate, at the substrate, or in an exhaust stream, the GaCl reacts with the NH₃ to form the GaN film. Reactions that occur at the substrate have the potential to yield the GaN film on the substrate, thereby resulting in crystal growth. Typical V/III ratios (the molar ratio of NH₃ to GaCl) are between 1 and 50 for this process. Note that the NH₃/HCl ratio need not equal the V/III ratio due to supplemental HCl injection downstream of the Ga source or incomplete reaction of HCl with the Ga source.

Block 214 represents, after a desired growth time has elapsed, the step of interrupting the gaseous HCl flow, returning the reactor pressure, and reducing the reactor's temperature to room temperature. The interrupting step further comprises including NH₃ in a gas stream to prevent decomposition of the GaN film during the reduction of the reactor's temperature. The reactor pressure may be returned to atmospheric pressure or held at a lower pressure, e.g., wherein the cooling is performed between 5 and 760 Torr.

Typical growth rates for the GaN film range from 1 to 400 microns per hour by this process. These growth rates are dependent on a number of growth parameters, including, but not limited to, the source and substrate temperatures, flow rates of the various gases into the system, the reactor geometry, etc., and can be varied over reasonably wide ranges while still yielding planar m-plane GaN films. The preferred values for most of these parameters will be specific to the growth reactor geometry.

The reference in the process steps above to the “final growth stage” refers to the observation that it is possible to planarize otherwise rough or defective films by concluding the growth stage with a step of suitable duration using the above-described conditions. The earlier stages of growth may incorporate any growth parameters that yield nominally m-plane oriented material, regardless of film quality or morphology.

Growth of the HVPE layer is terminated when the thickness of the non-polar or semi-polar GaN crystal reaches a value between about 2 mm and about 50 mm. In a specific embodiment, growth of the HVPE layer is terminated when the thickness of the non-polar or semi-polar GaN crystal reaches a value between about 5 mm and about 15 mm.

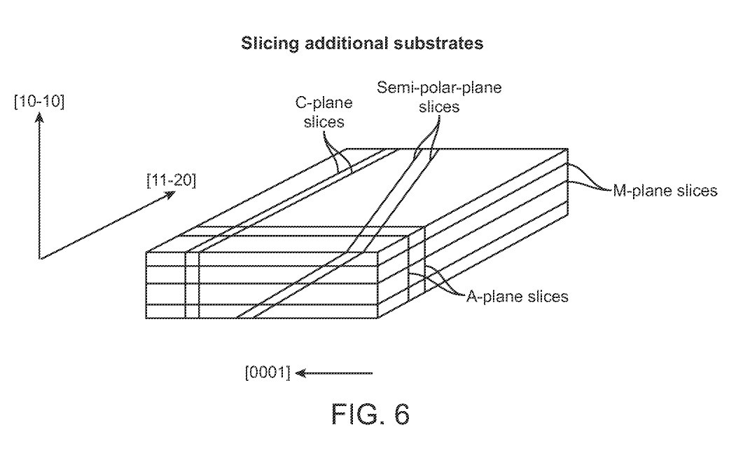

The HVPE-grown or ammonothermally-grown non-polar or semi-polar GaN crystal may be sliced into two or more wafers, as shown schematically in FIG. 6. In some embodiments, one or more slices are made parallel to the large area surface and the ammonothermally-laterally-grown non-polar slice seed crystal, in order to prepare two or more non-polar wafers. In one specific embodiment, the ammonothermally-laterally-grown non-polar slice seed crystal and the HVPE-grown or ammonothermally-grown non-polar GaN crystal have an m-plane orientation and two or more m-plane wafers are prepared by sawing parallel to the large m plane. In another specific embodiment, the ammonothermally-laterally-grown non-polar slice seed crystal and the HVPE-grown or ammonothermally-grown non-polar GaN crystal have an a-plane orientation and two or more a-plane wafers are prepared by sawing parallel to the large a plane. In still another specific embodiment, the ammonothermally-laterally-grown non-polar slice seed crystal and the HVPE-grown or ammonothermally-grown non-polar GaN crystal have an intermediate non-polar orientation (h,k,−(h+k),0) where h and k are integers and two or more (h,k,−(h+k),0)-plane wafers are prepared by sawing parallel to the large (h,k,−(h+k),0) plane. In some embodiments, the region of the GaN crystal corresponding to the ammonothermally-laterally-grown non-polar slice seed crystal is removed, so that the remainder of the crystal and the wafers sliced therefrom were grown by HVPE. In some embodiments, the wafers are lapped, polished, electrochemically polished, photoelectrochemically polished, reactive-ion-etched, and/or chemical-mechanically polished according to methods that are known in the art.

The wafers may contain several crystallites separated by low-angle grain boundaries but are free from coalescence fronts of the type observed in epitaxial lateral overgrowth. The wafers may have impurity concentrations of O, H, C, Na, and K below 1×10¹⁷ cm⁻³, 2×10¹⁷ cm⁻³, 1×10¹⁷ cm⁻³, 1×10¹⁶ cm⁻³, and 1×10¹⁶ cm⁻³, respectively, as quantified by calibrated secondary ion mass spectrometry (SIMS), glow discharge mass spectrometry (GDMS), interstitial gas analysis (IGA), or the like. The wafers may have impurity concentrations of O, H, C, Na, and K between about 1×10¹⁷ cm⁻³ and 1×10¹⁹ cm⁻³, between about 1×10¹⁷ cm⁻³ and 2×10¹⁹ cm⁻³, below 1×10¹⁷ cm⁻³, below 1×10¹⁶ cm⁻³, and below 1×10¹⁶ cm⁻³, respectively, as quantified by calibrated secondary ion mass spectrometry (SIMS). In another embodiment, the top wafers may have impurity concentrations of O, H, C, and at least one of Na and K between about 1×10¹⁷ cm⁻³ and 1×10¹⁹ cm⁻³, between about 1×10¹⁷ cm⁻³ and 2×10¹⁹ cm⁻³, below 1×10¹⁷ cm⁻³, and between about 3×10¹⁵ cm⁻³ and 1×10¹⁸ cm⁻³, respectively, as quantified by calibrated secondary ion mass spectrometry (SIMS). In still another embodiment, the wafers may have impurity concentrations of O, H, C, and at least one of F and Cl between about 1×10¹⁷ cm⁻³ and 1×10¹⁹ cm⁻³, between about 1×10¹⁷ cm⁻³ and 2×10¹⁹ cm⁻³, below 1×10¹⁷ cm⁻³, and between about 1×10¹⁵ cm⁻³ and 1×10¹⁷ cm⁻³, respectively, as quantified by calibrated secondary ion mass spectrometry (SIMS).

In a specific embodiment, the wafers have an m-plane orientation and the FWHM of the 1-100 x-ray rocking curve of at least one of the top surface and the bottom surface is below 1000 arc sec. In another embodiment, the FWHM of the 1-100 x-ray rocking curve of at least one of the top surface and the bottom surface is below 300 arc sec. In another embodiment, the FWHM of the 1-100 x-ray rocking curve of at least one of the top surface and the bottom surface is below 100 arc sec. The dislocation density on at least one large-area m-plane surface may be below 10⁶ cm⁻², below 10⁵ cm⁻², below 10⁴ cm⁻², below 10³ cm⁻², or below 10² cm⁻². The dislocation density through a c-plane in the wafers may be below 10⁵ cm⁻², below 10⁴ cm⁻², below 10³ cm⁻², or below 10² cm⁻².

In another specific embodiment, the wafers have an a-plane orientation and the FWHM of the 11-20 x-ray rocking curve of at least one of the top surface and the bottom surface is below 700 arc sec. In another embodiment, the FWHM of the 11-20 x-ray rocking curve of at least one of the top surface and the bottom surface is below 250 arc sec. In another embodiment, the FWHM of the 11-20 x-ray rocking curve of at least one of the top surface and the bottom surface is below 100 arc sec. The dislocation density on at least one large-area a-plane surface may be below 10⁶ cm⁻², below 10⁵ cm⁻², below 10⁴ cm⁻², below 10³ cm⁻², or below 10² cm⁻². The dislocation density through a c-plane in the wafers may be below 10⁵ cm⁻², below 10⁴ cm⁻², below 10³ cm⁻², or below 10² cm⁻².

In yet another specific embodiment, the wafers have a semi-polar orientation and the FWHM of the lowest-order semipolar symmetric x-ray rocking curve of at least one of the top surface and the bottom surface is below 1000 arc sec. In another embodiment, the FWHM of the semipolar symmetric x-ray rocking curve x-ray rocking curve of at least one of the top surface and the bottom surface is below 300 arc sec. In another embodiment, the FWHM of the semipolar symmetric x-ray rocking curve x-ray rocking curve of at least one of the top surface and the bottom surface is below 100 arc sec. The dislocation density on at least one large-area semi-polar plane surface may be below 10⁶ cm⁻², below 10⁵ cm⁻², below 10⁴ cm⁻², below 10³ cm⁻², or below 10² cm⁻². The dislocation density through a c-plane in the wafers may be below 10⁵ cm⁻², below 10⁴ cm⁻², below 10³ cm⁻², or below 10² cm⁻². In an embodiment, the semi-polar orientation is (11-2±2). In another it is (10-1±1). In yet another, (10-1±2). In still another, (10-1±3). In another, (10-1±4). In yet another, (20-2±1). In still another, (11-2±1). In yet another, (11-2±4). In another, (11-2±6).

In some embodiments, the wafer is used as a seed crystal for further bulk growth. In one specific embodiment, the further bulk growth comprises ammonothermal bulk crystal growth. In another specific embodiment, the further bulk growth comprises high temperature solution crystal growth, also known as flux crystal growth. In yet another specific embodiment, the further bulk growth comprises HVPE.

Further bulk growth by HVPE on the wafer may be performed according to the process outlined in FIG. 5. Some process adjustments may be necessary if the substrate orientation is different than that used to deposit a GaN layer on the ammonothermally-laterally-grown non-polar slice crystal. For example, it may be desirable to reduce the growth pressure relative to the growth pressure used for growth of non-polar GaN. In one specific embodiment, the growth pressure for growth on a semi-polar GaN wafer is 62.5 Torr, the ammonia flow is set to 1.0 slpm (standard liters per minute), and HCl (hydrogen chloride) flow over Ga (gallium) of 75 sccm (standard cubic centimeters per minute) is initiated to start the growth of GaN. Following growth of a thick layer, the GaN crystal is cooled and removed from the reactor. One or more slices may be performed as described above, followed by lapping, polishing, electrochemical polishing, photoelectrochemical polishing, reactive-ion-etching, and/or chemical-mechanical polishing according to methods that are known in the art.

The wafer may be incorporated into a semiconductor structure. The semiconductor structure may comprise at least one AlₓIn_{y}Ga_{(1-x-y)}N epitaxial layer, where 0≦x, y, x+y≦1. The epitaxial layer may be deposited on the wafer, for example, by metallorganic chemical vapor deposition (MOCVD) or by molecular beam epitaxy (MBE), according to methods that are known in the art. The semiconductor structure may form a portion of a gallium-nitride-based electronic device or optoelectronic device, such as a light emitting diode, a laser diode, a photodetector, an avalanche photodiode, a photovoltaic, a solar cell, a cell for photoelectrochemical splitting of water, a transistor, a rectifier, and a thyristor; one of a transistor, a rectifier, a Schottky rectifier, a thyristor, a p-i-n diode, a metal-semiconductor-metal diode, high-electron mobility transistor, a metal semiconductor field effect transistor, a metal oxide field effect transistor, a power metal oxide semiconductor field effect transistor, a power metal insulator semiconductor field effect transistor, a bipolar junction transistor, a metal insulator field effect transistor, a heterojunction bipolar transistor, a power insulated gate bipolar transistor, a power vertical junction field effect transistor, a cascade switch, an inner sub-band emitter, a quantum well infrared photodetector, a quantum dot infrared photodetector, and combinations thereof.

The above sequence of steps provides a method according to an embodiment of the present invention. In a specific embodiment, the present invention provides a method and resulting crystalline material provided by a high pressure apparatus having structured support members. Other alternatives can also be provided where steps are added, one or more steps are removed, or one or more steps are provided in a different sequence without departing from the scope of the claims herein.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A gallium based crystal comprising:
a first thickness of single crystalline material comprising gallium and nitrogen having a surface region with an m-plane orientation, the first thickness of single crystalline material having a c-direction length of greater than about 1 centimeter to about 30 centimeters and an a-direction length of greater than about 1 centimeter to about 30 centimeters, the first thickness of crystalline material having an m-direction thickness of at least 0.1 millimeter to about 10 millimeters; and
a second thickness of single crystalline material deposited overlying the surface region in the m-plane, the second thickness of single crystal material comprising gallium and nitrogen, the second thickness of single crystalline material having an m-direction thickness of at least 25 microns up to 50 millimeters;
wherein the first thickness and the second thickness are substantially free of stacking faults and coalescence fronts and the total impurity concentration in the second thickness is greater than the total impurity concentration in the first thickness.

2. The crystal of claim 1 wherein the second thickness of crystalline material is deposited ammonothermally, the second thickness of crystalline material having an m-plane dislocation density of 10⁶ cm⁻² and less and an unintentional impurity content of 10¹⁹ cm⁻³ and less.

3. The crystal of claim 1 wherein the first thickness of single crystal material comprises an m-oriented seed crystal whose central region is characterized by a c-plane dislocation density of between about 10⁴ cm⁻² to 10⁸ cm⁻² and having a 1-100 x-ray rocking curve full-width-at-half-maximum FWHM less than 300 arc seconds and a first total impurity concentration below about 10¹⁸ cm⁻³ and an oxygen concentration below about 10¹⁷ cm⁻³, a hydrogen concentration below about 2×10¹⁷ cm⁻³, and a sodium concentration below about 10¹⁶ cm⁻³ and a laterally grown single crystalline region in the c-direction by a c-plane dislocation density of between about 10⁴ cm⁻² to 10⁸ cm⁻² and having a 1-100 x-ray rocking curve full-width-at-half-maximum FWHM less than 300 arc seconds and a second total impurity concentration, the second total impurity concentration being higher than the first total impurity concentration.

4. The crystal of claim 3 wherein the second total impurity concentration is less than about 10²⁰ cm⁻³ and greater than about 10¹⁶ cm⁻³.

5. The crystal of claim 3, wherein the second thickness of crystalline material has an m-plane dislocation density of 10⁵ cm⁻² and less, a c-plane dislocation density of 10⁴ cm⁻² and less, a hydrogen concentration between 2×10¹⁷ cm⁻³ and 2×10¹⁹ cm⁻³, and a 1-100 x-ray rocking curve full-width-at-half-maximum FWHM less than 150 arc seconds.

6. The crystal of claim 5, wherein the second thickness of crystalline material has an m-plane dislocation density of 10⁴ cm⁻² and less, a c-plane dislocation density of 10³ cm⁻² and less, a hydrogen concentration between 2×10¹⁷ cm⁻³ and 2×10¹⁹ cm⁻³, and a 1-100 x-ray rocking curve full-width-at-half-maximum FWHM less than 100 arc seconds.

7. A gallium based crystal comprising:
a first thickness of single crystalline material comprising gallium and nitrogen having a surface region with an a-plane orientation, the first thickness of single crystalline material having a c-direction length of greater than about 1 centimeter to about 30 centimeters and an m-direction length of greater than about 1 centimeter to about 30 centimeters, the first thickness of crystalline material having an m-direction thickness of at least 0.1 millimeter to about 10 millimeters; and
a second thickness of single crystalline material deposited overlying the surface region in the a-plane, the second thickness of single crystal material comprising gallium and nitrogen, the second thickness of single crystalline material having an a-direction thickness of at least 25 microns up to 50 millimeters;
wherein the first thickness and the second thickness are substantially free of stacking faults and coalescence fronts and the total impurity concentration in the second thickness is greater than the total impurity concentration in the first thickness.

8. The crystal of claim 7 wherein the second thickness of crystalline material is deposited ammonothermally, the second thickness of crystalline material having an a-plane dislocation density of 10⁶ cm⁻² and less and an unintentional impurity content of 10¹⁹ cm⁻³ and less.

9. The crystal of claim 7 wherein the first thickness of single crystal material comprises an a-oriented seed crystal whose central region is characterized by a c-plane dislocation density of between about 10⁴ cm⁻² to 10⁸ cm⁻² and having a 11-20 x-ray rocking curve full-width-at-half-maximum FWHM less than 300 arc seconds and a first total impurity concentration below about 10¹⁸ cm³ and an oxygen concentration below about 10¹⁷ cm⁻³, a hydrogen concentration below about 2×10¹⁷ cm³, and a sodium concentration below about 10¹⁶ cm⁻³ and a laterally grown single crystalline region in the c-direction by a c-plane dislocation density of between about 10⁴ cm² to 10⁸ cm⁻² and having a 11-20 x-ray rocking curve full-width-at-half-maximum FWHM less than 300 arc seconds and a second total impurity concentration, the second total impurity concentration being higher than the first total impurity concentration.

10. The crystal of claim 9 wherein the second total impurity concentration is less than about 10²⁰ cm⁻³ and greater than about 10¹⁶ cm⁻³.

11. The crystal of claim 9, wherein the second thickness of crystalline material has an a-plane dislocation density of 10⁵ cm⁻² and less, a c-plane dislocation density of 10⁴ cm⁻² and less, a hydrogen concentration between 2×10¹⁷ cm⁻³ and 2×10¹⁹ cm⁻³, and a 11-20 x-ray rocking curve full-width-at-half-maximum FWHM less than 150 arc seconds.

12. The crystal of claim 11, wherein the second thickness of crystalline material has an a-plane dislocation density of 10⁴ cm⁻² and less, a c-plane dislocation density of 10³ cm⁻² and less, a hydrogen concentration between 2×10¹⁷ cm⁻³ and 2×10¹⁹ cm⁻³, and a 11-20 x-ray rocking curve full-width-at-half-maximum FWHM less than 100 arc seconds.

13. A gallium based crystal comprising:
a first thickness of single crystalline material comprising gallium and nitrogen having a surface region with a semi-polar-plane orientation, the first thickness of single crystalline material having a length in two orthogonal directions of greater than about 1 centimeter to about 30 centimeters, the first thickness of crystalline material having a semi-polar-direction thickness of at least 0.1 millimeter to about 10 millimeters; and
a second thickness of single crystalline material deposited overlying the surface region in the semi-polar-plane, the second thickness of single crystal material comprising gallium and nitrogen, the second thickness of single crystalline material having a semi-polar-direction thickness of at least 25 microns up to 50 millimeters;
wherein the first thickness and the second thickness are substantially free of stacking faults and coalescence fronts and the total impurity concentration in the second thickness is greater than the total impurity concentration in the first thickness.

14. The crystal of claim 13 wherein the second thickness of crystalline material is deposited ammonothermally, the second thickness of crystalline material having a semi-polar-plane dislocation density of 10⁶ cm⁻² and less and an unintentional impurity content of 10¹⁹ cm⁻³ and less.

15. The crystal of claim 13 wherein the first thickness of single crystal material comprises a semi-polar-oriented seed crystal whose central region is characterized by a c-plane dislocation density of between about 10⁴ cm⁻² to 10⁸ cm⁻² and having a lowest-order semi-polar symmetric x-ray rocking curve full-width-at-half-maximum FWHM less than 300 arc seconds and a first total impurity concentration below about 10¹⁸ cm³ and an oxygen concentration below about 10¹⁷ cm⁻³, a hydrogen concentration below about 2×10¹⁷ cm³, and a sodium concentration below about 10¹⁶ cm⁻³ and a laterally grown single crystalline region having a c-plane dislocation density of between about 10⁴ cm² to 10⁸ cm⁻² and having a lowest-order semi-polar symmetric x-ray rocking curve full-width-at-half-maximum FWHM less than 300 arc seconds and a second total impurity concentration, the second total impurity concentration being higher than the first total impurity concentration.

16. The crystal of claim 13 wherein the second total impurity concentration is less than about 10²⁰ cm⁻³ and greater than about 10¹⁶ cm⁻³.

17. The crystal of claim 13, wherein the second thickness of crystalline material has a semi-polar-plane dislocation density of 10⁵ cm⁻² and less, a c-plane dislocation density of 10⁴ cm⁻² and less, a hydrogen concentration between 2×10¹⁷ cm⁻³ and 2×10¹⁹ cm⁻³, and a lowest-order semi-polar symmetric x-ray rocking curve full-width-at-half-maximum FWHM less than 150 arc seconds.

18. The crystal of claim 13, wherein the second thickness of crystalline material has a semi-polar-plane dislocation density of 10⁴ cm⁻² and less, a c-plane dislocation density of 10³ cm⁻² and less, a hydrogen concentration between 2×10¹⁷ cm⁻³ and 2×10¹⁹ cm⁻³, and a lowest-order semi-polar symmetric x-ray rocking curve full-width-at-half-maximum FWHM less than 100 arc seconds.

19. A gallium nitride thickness of material comprising:
a first thickness of single crystal material comprising an m-plane oriented crystal characterized by a c-plane dislocation density of between about 10⁴ cm⁻² to 10⁸ cm⁻² and having a 1-100 x-ray rocking curve full-width-at-half-maximum FWHM less than about 150 arc seconds and a first total impurity concentration below about 10¹⁸ cm⁻³ and an oxygen concentration below about 10¹⁷ cm⁻³ and a hydrogen concentration below about 2×10¹⁷ cm⁻³, and a sodium concentration below about 10¹⁶ cm⁻³ and a laterally grown single crystalline region in the c-direction with a c-plane dislocation density of between about 10⁴ cm⁻² to 10⁸ cm⁻² and having a 1-100 x-ray rocking curve full-width-at-half-maximum FWHM less than about 150 arc seconds and a second total impurity concentration, the second total impurity concentration being higher than the first total impurity concentration.

20. The thickness of material of claim 19 further comprising an a-direction laterally grown single crystalline region coupled to the m-oriented crystal.

21. A method for slicing one or more substrates comprising:
providing a gallium based substrate comprising a first thickness of single crystalline material comprising gallium and nitrogen having a surface region in an m-plane, the first thickness of single crystalline material having a c-direction length of greater than about 1 centimeter to about 30 centimeters and an a-direction length of greater than about 1 centimeter to about 30 centimeters, the first thickness of crystalline material having an m-direction thickness of at least 0.1 millimeter to about 10 millimeters; and a second thickness of single crystalline material deposited overlying the surface region in the m-plane, the second thickness of single crystal material comprising gallium and nitrogen, the second thickness of single crystalline material having an m-direction thickness of at least 25 microns up to 50 millimeters;
orienting the gallium based substrate; and
slicing a thickness of substrate material from the gallium based substrate to remove the thickness of substrate material from a remaining portion of the gallium based substrate, the thickness of substrate material being about 0.1 millimeter and greater.

22. The method of claim 21 wherein the thickness of substrate material is characterized as having a c-plane face.

23. The method of claim 21 wherein the thickness of substrate material is characterized as having an m-plane face.

24. The method of claim 21 wherein the thickness of substrate material is characterized as having an a-plane face.

25. The method of claim 21 wherein the slicing comprises a sawing operation.

26. The method of claim 21 wherein the thickness of substrate material is characterized as having a semi-polar face.

27. A method for fabricating a seed crystal, the method comprising:
providing an m-plane oriented seed crystal characterized by a c-plane dislocation density of between about 10⁴ cm⁻² to 10⁸ cm⁻² and having a 1-100 x-ray rocking curve full-width-at-half-maximum FWHM less than about 300 arc seconds and a first total impurity concentration below about 10¹⁸ cm⁻³ and an oxygen concentration below about 10¹⁷ cm⁻³ and a hydrogen concentration below about 2×10¹⁷ cm⁻³, and a sodium concentration below about 10¹⁶ cm⁻³; and
growing in a lateral direction a single crystalline thickness of material in either or both a +c-direction and −c direction using first ammonothermal process, the single crystalline thickness of material having a c-plane dislocation density of between about 10⁴ cm⁻² to 10⁸ cm⁻² and having a 1-100 x-ray rocking curve full-width-at-half-maximum FWHM less than about 300 arc seconds and a second total impurity concentration, the second total impurity concentration being higher than the first total impurity concentration.

28. The method of claim 27 wherein the growing in the lateral direction occurs at a faster rate in either or both the +c direction and −c direction than a growth rate in the m-direction.

29. The method of claim 27 wherein c-direction growth is larger than m-direction growth by factor of two to ten and greater.

30. The method of claim 27 wherein the m-plane oriented seed crystal and the single crystalline thickness of material in the lateral direction have a total length about 1 centimeters to about 20 centimeters.

31. The method of claim 27 further comprising growing in an a-direction a thickness of single crystalline material coupled to the m-seed crystal.

32. The method of claim 27 further comprising growing in a lateral direction a second single crystalline thickness of material in an a-direction using a second ammonothermal process, the single crystalline thickness of material having a c-plane dislocation density of between about 10⁴ cm⁻² to 10⁸ cm⁻² and having a 1-100 x-ray rocking curve full-width-at-half-maximum FWHM less than about 300 arc seconds and a second total impurity concentration, the second total impurity concentration being higher than the first total impurity concentration.

33. The method of claim 27 wherein the m-plane oriented seed crystal and the single crystalline thickness of material in the lateral direction have a total length about 1 centimeters to about 20 centimeters.

34. A method of fabricating a gallium based substrate, the method comprising:
providing a first thickness of single crystalline material comprising gallium and nitrogen having a surface region in an m-plane orientation, the first thickness of single crystalline material having a c-direction length of greater than about 1 centimeter to about 30 centimeters and an a-direction length of greater than about 1 centimeter to about 30 centimeters, the first thickness of crystalline material having an m-direction thickness of at least 0.1 millimeter to about 10 millimeters; and
growing a second thickness of single crystalline material using a deposition process overlying the surface region in the m-plane, the second thickness of single crystal material comprising gallium and nitrogen, the second thickness of single crystalline material having an m-direction thickness of at least 25 microns up to 50 millimeters.

35. The method of claim 34 wherein the deposition process comprises a hydride vapor phase epitaxy.

36. The method of claim 34 wherein the deposition process comprises an ammonothermal crystal growth process.

37. The method of claim 34 wherein the second thickness of single crystalline material is a nitride based material selected from GaN, AlN, InN, AlGaN, InGaN, and AlInGaN.

38. The method of claim 34 wherein the growing of the second thickness of single crystalline material has a growth rate of about 25 microns per hour to about 500 microns per hour.

39. A method of fabricating a gallium based substrate, the method comprising:
providing a first thickness of single crystalline material comprising gallium and nitrogen having a surface region in a semi-polar-plane orientation, the first thickness of single crystalline material having a length in two orthogonal directions of greater than about 1 centimeter to about 30 centimeters, the first thickness of crystalline material having a semi-polar-direction thickness of at least 0.1 millimeter; and
growing a second thickness of single crystalline material using a deposition process overlying the surface region in the m-plane, the second thickness of single crystal material comprising gallium and nitrogen, the second thickness of single crystalline material having a thickness of at least 25 microns.

40. The method of claim 39 wherein the deposition process comprises a hydride vapor phase epitaxy.

41. The method of claim 39 wherein the deposition process comprises an ammonothermal crystal growth process.

42. The method of claim 39 wherein the second thickness of single crystalline material is a nitride based material selected from GaN, AlN, InN, AlGaN, InGaN, and AlInGaN.

43. A composite seed crystal comprising a first region of first gallium and nitrogen containing material and a second region of second gallium and nitrogen containing material.

44. A method of fabricating devices comprising:
providing a composite seed crystal comprising a first region of first gallium and nitrogen containing material and a second region of second gallium and nitrogen containing material; forming one or more thicknesses of gallium and nitrogen containing material overlying one or more portions of the composite seed crystal; and
using one or more regions of the one or more thicknesses of the gallium and nitrogen containing material for fabricating of at least an optical and/or an electrical device.

45. A method for fabricating a gallium containing substrate material, the method comprising:
providing a composite seed crystal comprising a first region and a second region, the composite seed crystal being composed of a gallium containing material, the first region being characterized by a first set of impurity concentrations and the second region being characterized by a second set of impurity concentrations, wherein a concentration of at least one of hydrogen, oxygen, sodium, potassium, fluorine, or chlorine differs by at least a factor of three between the first region and the second region;
growing a thickness of material overlying the composite seed material to cause formation of a gallium containing boule having a diameter of 1 centimeter and greater and a thickness of 1 millimeter and greater; and
slicing the gallium containing boule to form one or more gallium containing substrates.

46. The method of claim 45 wherein the concentration of at least one of hydrogen, oxygen, sodium, potassium, fluorine, or chlorine differs by at least a factor of ten between the first region and the second region.

47. The method of claim 45 wherein the transition between the first set of impurity levels and the second set of impurity levels occurs within a transition thickness of less than less than about 10 microns.

48. The method of claim 45 further comprising forming at least one or more optical or electrical devices on one or more of the gallium containing substrates.

49. The method of claim 45 wherein the impurity concentrations of oxygen (O), hydrogen (H), carbon (C), sodium (Na), potassium (K), fluorine (F), and chlorine (Cl) within the first region are below about 1×10¹⁷ cm⁻³, 2×10¹⁷ cm⁻³, 1×10¹⁷ cm⁻³, 1×10¹⁶ cm⁻³, 1×10¹⁶ cm⁻³, 1×10¹⁵cm⁻³ and 1×10¹⁵ cm⁻³, respectively, and the impurity concentrations of oxygen (O), hydrogen (H), and carbon (C) within the second region are between about 1×10¹⁷ cm⁻³ and 1×10¹⁹ cm⁻³, between about 1×10¹⁷ cm⁻³ and 2×10¹⁹ cm⁻³, and below about 1×10¹⁷ cm⁻³, respectively.

50. The method of claim 45 wherein the impurity concentration of at least one of Na and K within the second region is between about 3×10¹⁵ cm⁻³ and 1×10¹⁸ cm⁻³.

51. The method of claim 45 wherein the impurity concentration of at least one of F and Cl within the second region is between about 1×10¹⁵ cm⁻³ and 1×10¹⁷ cm⁻³.

52. The method of claim 45 wherein the impurity concentrations of oxygen (O), hydrogen (H), and carbon (C) within the first region are below about 3×10¹⁶ cm⁻³, 1×10¹⁷ cm⁻³, and 3×10¹⁶ cm⁻³, respectively.

53. The method of claim 45, wherein the composite seed crystal further comprises a third set of impurity concentrations, wherein a concentration of at least one of hydrogen, oxygen, sodium, potassium, fluorine, or chlorine differs by at least a factor of three between the second region and the third region.
